(19) United States
(12) Patent Application Publication
(10) Pub. No.: US 2023/0013088 A1
(43) Pub. Date: Jan. 19, 2023

(54) IMAGING DEVICE AND METHOD OF MANUFACTURING IMAGING DEVICE

(71) Applicant: SONY SEMICONDUCTOR SOLUTIONS CORPORATION, KANAGAWA (JP)

(72) Inventors: KATSUJI KIMURA, KANAGAWA (JP); YOUJI SAKIOKA, KANAGAWA (JP); HIROKAZU SEKI, KUMAMOTO (JP)

(21) Appl. No.: 17/757,603

(22) PCT Filed: Dec. 15, 2020
(86) PCT No.: PCT/JP2020/046758

§ 371 Date: Jun. 17, 2022

(30) Foreign Application Priority Data
Dec. 27, 2019 (JP) 2019-239362

(51) Int. Cl. H01L 27/146

(52) U.S. Cl. CPC H01L 27/14627; H01L 27/1462; H01L 27/14649; H01L 27/14685

(57) ABSTRACT

Provided are an imaging device having more superior optical characteristics, a method of manufacturing the imaging device, and an electronic device at a lower cost. An imaging device according to an embodiment includes: an imaging element (10) including a solid-state imaging element (100) on which a light receiving surface in which light receiving elements are arranged in a two-dimensional lattice shape is formed, and a protection member (101, 102) disposed on a side of the light receiving surface with respect to the solid-state imaging element, in which the imaging element includes a curved portion curved from the light receiving surface of the solid-state imaging element toward a surface on an opposite side of the light receiving surface.

### FIELD

The present disclosure relates to an imaging device and a method of manufacturing the imaging device.

### BACKGROUND

In recent years, in a mobile terminal device with a camera and an electronic device including an imaging element such as a digital still camera, the number of pixels in the device is increasing and the size of the device is decreasing. With the increase in the number of pixels and the reduction in size of the device, a pitch of one pixel of an imaging element such as a charge coupled device (CCD) sensor or a complementary metal oxide semiconductor (CMOS) image sensor mounted as a solid-state imaging element in the device becomes very small, and small diaphragm diffraction of a lens occurs, which leads to deterioration of optical characteristics.

It is known that deterioration of optical characteristics such as small diaphragm diffraction of a lens can be suppressed by increasing an aperture of the lens. On the other hand, when the aperture of the lens is increased, there is a possibility that a decrease in peripheral light amount, field curvature, a decrease in peripheral resolution, and the like, which are caused by optical characteristics, occur. Furthermore, in order to eliminate these optical characteristics, techniques such as advanced digital signal processing have been developed together with improvement of a material of the lens, increase in the number of lenses, and development of a technique for making a structure of the lens aspheric.

All the above-described techniques for eliminating the optical characteristics that occur when the lens aperture is increased are high in design difficulty and manufacturing difficulty, thus resulting in a high cost. In addition, it is generally known that there is a limit to downsizing of an imaging device with respect to further narrowing the pitch of the pixels of the solid-state imaging element and expanding the lens aperture in the future.

In order to eliminate the optical characteristics that occur when the lens aperture is increased, a method of curving a solid-state imaging element in accordance with an image plane on which an image is formed by a lens has been developed and proposed. By curving the solid-state imaging element in accordance with the image plane on which an image is formed by the lens, it is possible to suppress deterioration of the optical characteristics, which occurs when the lens aperture is increased as described above, and to obtain a good image. As described above, in order to curve the solid-state imaging element in accordance with the image plane on which an image is formed by the lens, a technique has been proposed in which a curved portion corresponding to a curvature of the lens is provided on a pedestal board, and the solid-state imaging element is curved by suction in accordance with the curved portion of the pedestal board (for example, Patent Literature 1 and Patent Literature 2).

### CITATION LIST

### Patent Literature

Patent Literature 1: JP 2005-260436 A

Patent Literature 2: JP 2015-192074 A

Patent Literature 3: US 2017/0301710 A

### SUMMARY

### Technical Problem

However, in order to curve the solid-state imaging element by this suction, it is necessary to perform the suction over a long time so as not to crack the solid-state imaging element. Therefore, this is disadvantageous in terms of productivity. This may cause an increase in cost.

An object of the present disclosure is to provide an imaging device having more excellent optical characteristics and a method of manufacturing the imaging device at a lower cost.

### Solution to Problem

For solving the problem described above, an imaging device according to one aspect of the present disclosure has an imaging element including a solid-state imaging element on which a light receiving surface in which light receiving elements are arranged in a two-dimensional lattice pattern is formed, and a protection member disposed on a side of the light receiving surface with respect to the solid-state imaging element, wherein the imaging element includes a curved portion curved from the light receiving surface of the solid-state imaging element toward a surface on an opposite side of the light receiving surface.

### BRIEF DESCRIPTION OF DRAWINGS

FIG. 1 is a cross-sectional view illustrating an example of a structure of an imaging device according to a first embodiment.

FIG. 2 is a cross-sectional view illustrating a structure of an example of a CSP solid-state imaging element applicable to the first embodiment.

FIG. 3A is a schematic diagram for explaining a method of manufacturing an imaging element according to the first embodiment.

FIG. 3B is a schematic diagram for explaining the method of manufacturing the imaging element according to the first embodiment.

FIG. 3C is a schematic diagram for explaining the method of manufacturing the imaging element according to the first embodiment.

FIG. 3D is a schematic diagram for explaining the method of manufacturing the imaging element according to the first embodiment.

FIG. 3E is a schematic diagram for explaining the method of manufacturing the imaging element according to the first embodiment.

FIG. 3F is a schematic diagram for explaining the method of manufacturing the imaging element according to the first embodiment.

FIG. 4 is a graph illustrating an example of a relationship between a Sag amount and a thickness of a CSP solid-state imaging element applicable to the first embodiment.

FIG. 5 is a graph illustrating an example of a relationship between a Sag amount and a pressing pressure applicable to the first embodiment.

FIG. 6A is a schematic view illustrating a first example of a pedestal shape applicable to the first embodiment.

FIG. 6B is a schematic view illustrating a second example of the pedestal shape applicable to the first embodiment.

FIG. 6C is a schematic view illustrating a third example of the pedestal shape applicable to the first embodiment.

FIG. 7 is a cross-sectional view illustrating an example of a structure of an imaging element in a case where a pedestal having the pedestal shape of the second example according to the first embodiment is used.

FIG. 8A is a schematic diagram for explaining an imaging device according to a first modification example of the first embodiment.

FIG. 8B is a schematic diagram for explaining the imaging device according to the first modification example of the first embodiment.

FIG. 9 is a cross-sectional view illustrating an example of a structure of an imaging element according to a second modification example of the first embodiment.

FIG. 10 is a block diagram illustrating a configuration of an example of an imaging device to which an imaging element according to the present disclosure is applied.

FIG. 11 is a diagram illustrating a usage example of an imaging device to which a technique of the present disclosure is applied.

FIG. 12 is a diagram illustrating an example of a schematic configuration of an endoscopic surgery system.

FIG. 13 is a block diagram illustrating an example of functional configurations of a camera head and a CCU.

FIG. 14 is a block diagram illustrating an example of a schematic configuration of a vehicle control system.

FIG. 15 is an explanatory diagram illustrating an example of installation positions of a vehicle exterior information detection unit and an imaging unit.

### DESCRIPTION OF EMBODIMENTS

Hereinafter, embodiments of the present disclosure will be described in detail with reference to the drawings. Note that, in the following embodiments, the same parts are denoted by the same reference signs, and redundant description will be omitted.

Hereinafter, the embodiments of the present disclosure will be described in the following order.

1. First Embodiment

1-0-1. Structure of Imaging Element According to First Embodiment

1-0-2. Method of Manufacturing Imaging Device According to First Embodiment

1-0-3. Details of Pressing Process

1-0-4. Comparison With Existing Techniques

1-0-5. Other Shapes of Pedestal

1-1. First Modification Example

1-2. Second Modification Example

2. Second Embodiment

3. Third Embodiment

3-1. Application Example to Endoscopic Surgery System

3-2. Application Example to Mobile Body

### 1. First Embodiment

First, a first embodiment of the present disclosure will be described. In the first embodiment, a solid-state imaging element is used in which a sensor unit including a plurality of light receiving elements that are arranged in a two-dimensional lattice pattern and convert received light into an electric signal by photoelectric conversion, respectively, and a glass substrate for fixing the sensor unit and protecting a light receiving surface are stacked with a resin layer interposed therebetween. The solid-state imaging element is configured by a cavityless shape (hereinafter abbreviated as cavi-less shape) in which a layer between the sensor unit and the glass substrate is filled with a resin, and no cavity layer (void layer) is provided.

In the first embodiment, the solid-state imaging element having the cavi-less shape is curved in a direction of a surface on an opposite side of the light receiving surface of the solid-state imaging element. More specifically, a pedestal having a recess corresponding to a shape desired to curve the solid-state imaging element, and a pushing tool having a convex portion corresponding to the recess are used, and the solid-state imaging element is curved by applying a predetermined pressure to the solid-state imaging element using the pushing tool in a state where the solid-state imaging element is placed on the pedestal. The curved solid-state imaging element is fixed to the pedestal.

As described above, by curving the solid-state imaging element so as to have the recess when viewed from the light receiving surface, optical characteristics can be improved. Furthermore, in the first embodiment, since a solid-state imaging element with a cavi-less shape is used, it is possible to curve the solid-state imaging element without causing breakage or the like of the glass substrate by applying the pressure by the pushing tool.

(1-0-1. Structure of Imaging Element According to First Embodiment)

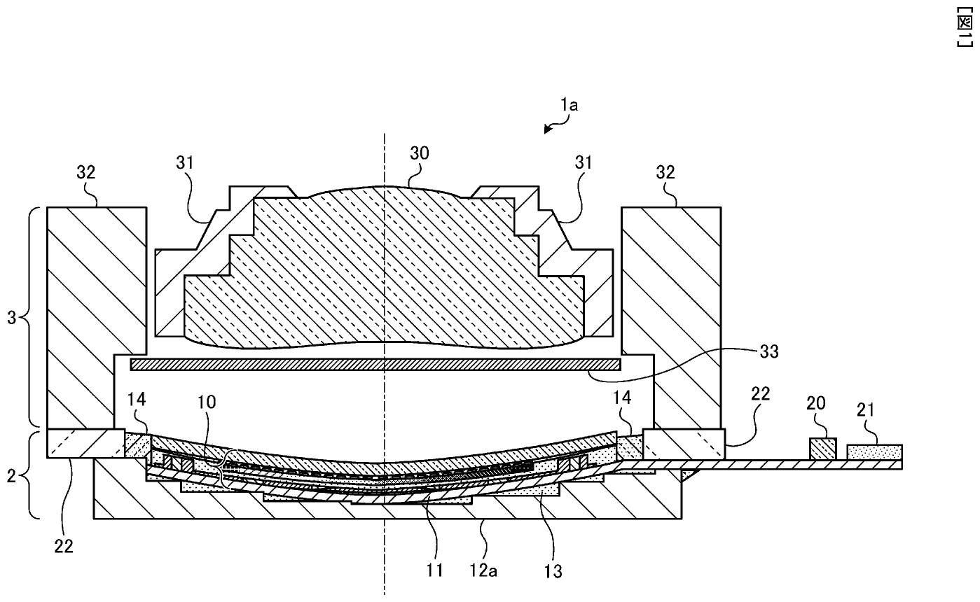

FIG. 1 is a cross-sectional view illustrating an example of a structure of an imaging device according to the first embodiment. The cross-sectional view of FIG. 1 illustrates an example of a cross section taken along a plane including an optical axis of light incident on the imaging device 1a. In FIG. 1, the imaging device 1a includes an element unit 2 and an optical unit 3. The element unit 2 includes a CSP solid-state imaging element 10, a circuit board 11, and a pedestal 12a. The optical unit 3 includes a lens group 30, a lens holder 31 that holds the lens group 30, an actuator 32, and an infrared cut filter 33.

In the optical unit 3, the lens group 30 includes one or more lenses, and forms a subject image on the light receiving surface of the CSP solid-state imaging element 10. In the example of FIG. 1, the lens of the lens group 30 that is disposed at a position closest to the CSP solid-state imaging element 10 is an aspherical lens having a curved shape in which an image surface has an extreme value. The actuator 32 drives a predetermined lens included in the lens group 30 in a vertical direction and a horizontal direction (and a front-rear direction) in FIG. 1 in a direction opposite to the CSP solid-state imaging element 10, for example. As a result, at least one of an autofocus function and a camera shake correction function is realized.

Note that the actuator 32 may have either the function of autofocus or the function of camera shake correction, or may be a simple lens holder having neither the function of autofocus nor the function of camera shake correction. Furthermore, the autofocus and the camera shake correction may be realized by means other than the actuator 32, such as image processing.

The infrared cut filter 33 cuts light having a wavelength component other than a wavelength component of visible light, particularly, light having a wavelength component of infrared light, from light condensed by the lens group 30.

In the element unit 2, the CSP solid-state imaging element 10 functions as a sensor unit including an image sensor using a complementary metal oxide semiconductor (CMOS), which will be described in detail later, and has a chip size package (CSP) structure. The image sensor is not limited thereto, and may be an image sensor using a charge coupled device (CCD).

The circuit board 11 is configured using a flexible thin material, and the CSP solid-state imaging element 10 is mounted. The CSP solid-state imaging element 10 is electrically connected to the circuit board 11 using solder or the like. A semiconductor component 20 such as a large scale integration (LSI) such as a capacitor, a resistive element, and an autofocus driver for driving the actuator 32, and a connector 21 for outputting an imaging signal imaged by the CSP solid-state imaging element 10 to the outside are further disposed on the circuit board 11 as necessary.

Further, a spacer 22 for fixing the actuator 32 to the circuit board 11 is disposed on the circuit board 11. The spacer 22 is preferably formed of a material capable of suppressing reflection of light. Examples of a material for realizing such a material include a synthetic resin colored in matte black. A predetermined circuit can be built in the spacer 22.

A fixing agent 14 is filled between the spacer 22 and the CSP solid-state imaging element 10. The fixing agent 14 has a function of preventing the CSP solid-state imaging element 10 from peeling from the circuit board 11 and reducing stray light from a side surface of the CSP solid-state imaging element 10. For example, the fixing agent 14 can be formed using a matte black synthetic resin or a synthetic resin colored in matte black.

As illustrated in FIG. 1, in the imaging device 1a according to the first embodiment, the CSP solid-state imaging element 10 has a shape curved in a direction opposite to the lens group 30. The curved shape of the CSP solid-state imaging element 10 can be, for example, a shape in accordance with performance such as field curvature correction. Furthermore, for example, optical characteristics of the lens group 30 can be designed so as to be applied to the curved shape of the CSP solid-state imaging element 10. In the example of FIG. 1, the CSP solid-state imaging element 10 is curved in a curved shape having one vertex in a direction opposite to the light receiving surface.

The imaging device 1a further includes a pedestal 12a for holding the curved shape of the CSP solid-state imaging element 10. The CSP solid-state imaging element 10 is curved along a seat surface of the pedestal 12a on which the CSP solid-state imaging element 10 is disposed. In the example of FIG. 1, the seat surface of the pedestal 12a has a stepped shape, and each edge of the stepped shape abuts on each corresponding position of the curved CSP solid-state imaging element 10. Furthermore, each gap between a curved portion of the CSP solid-state imaging element 10 and the stepped shape is a resin reservoir, and the resin reservoir is filled with an adhesive 13 made of, for example, resin for fixing the CSP solid-state imaging element 10 to the pedestal 12a.

Note that a material of the adhesive 13 for fixing the CSP solid-state imaging element 10 to the pedestal 12a is changed according to the configuration of the imaging device 1a or the like. For example, the material of the adhesive 13 is changed according to a thickness of the CSP solid-state imaging element 10 or the circuit board 11. All these modifiable adhesive materials are within the scope of the present disclosure.

Further, the pedestal 12a for forming the curved shape of the CSP solid-state imaging element 10 is changed in accordance with the characteristics of the lens group 30, and changes in the shape, arrangement, and thickness of the pedestal 12a are all within the scope of the present disclosure.

Furthermore, the circuit board 11 is sufficiently soft and flexible for molding the curved shape of the CSP solid-state imaging element 10. In addition, a thickness of the circuit board 11 is adjusted by wiring or the like formed on the circuit board 11.

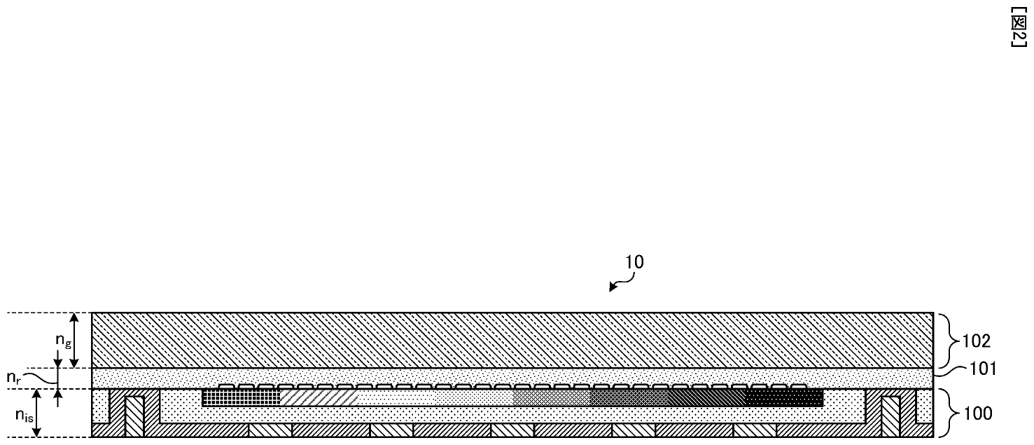

FIG. 2 is a cross-sectional view illustrating a structure of an example of the CSP solid-state imaging element 10 applicable to the first embodiment. In FIG. 2, the CSP solid-state imaging element 10 includes a solid-state imaging element 100, a resin layer 101, and a glass substrate 102. The solid-state imaging element 100 includes a plurality of light receiving elements (for example, photodiodes) arranged in a two-dimensional lattice pattern, and a drive circuit for driving each light receiving element. The solid-state imaging element 100 may further include a signal processing circuit that performs signal processing such as correlated double sampling (CDS) on a signal read from each light receiving element. In the solid-state imaging element 100, each light receiving element generates a charge according to an amount of incident light by photoelectric conversion. The solid-state imaging element 100 outputs a pixel signal by an electric signal corresponding to the charge generated in each light receiving element. The solid-state imaging element 100 is electrically connected to the outside (for example, the circuit board 11) via a connection portion provided in the CSP solid-state imaging element 10.

More specifically, in the solid-state imaging element 100, for example, a color filter that transmits light of any wavelength region of red (R), green (G), and blue (B) is disposed with respect to an incident part where light is incident in each light receiving element, and further, a microlens is disposed on an incident side of the color filter. The surface on which the microlens is disposed is a light receiving surface of the solid-state imaging element 100 (an upper surface in FIG. 2).

In the CSP solid-state imaging element 10, the transparent glass substrate 102 is provided on a side of the light receiving surface of the solid-state imaging element 100. The glass substrate 102 is adhered to the light receiving surface of the solid-state imaging element 100 with an adhesive as a transparent member, and is fixedly disposed with respect to the solid-state imaging element 100. The adhesive is filled between the solid-state imaging element 100 and the glass substrate 102 as the resin layer 101. Further, the glass substrate 102 has functions of fixing the solid-state imaging element 100 and protecting the light receiving surface.

In the CSP solid-state imaging element 10 configured as described above, the resin layer 101 is in close contact with the solid-state imaging element 100, and the glass substrate 102 is in close contact with a surface of the resin layer 101 on an opposite side of a surface with which the solid-state imaging element 100 is in close contact. Since the resin layer 101 fills a space between the solid-state imaging element 100 and the glass substrate 102, and the CSP solid-state imaging element 10 does not include a cavity layer (void layer) therein, even if a pressure is applied to the CSP solid-state imaging element 10 by a pushing tool, the solid-state imaging element can be curved without causing breakage or the like of the glass substrate.

Note that, in a case where a refractive index of the solid-state imaging element 100 is nᵢₛ, a refractive index of the resin layer 101 is nᵣ, and a refractive index of the glass substrate 102 is n_{g}, a relationship among the refractive indexes nᵢₛ, nᵣ, and n_{g} is, for example, as in the following formula (1).

nᵢₛ>nᵣ≈n_{g} (1)

Note that, in the above description, the CSP solid-state imaging element 10 includes the solid-state imaging element 100, the resin layer 101, and the glass substrate 102, but this is not limited to this example. That is, as long as the CSP solid-state imaging element 10 includes the solid-state imaging element 100, and a protection member that is close contact with the light receiving surface and protects the light receiving surface of the solid-state imaging element 100, another structure can be applied. As the protection member, for example, only the resin layer 101 or only the glass substrate 102 can be applied in addition to the combination of the resin layer 101 and the glass substrate 102 described above.

(1-0-2. Method of Manufacturing Imaging Device According to First Embodiment)

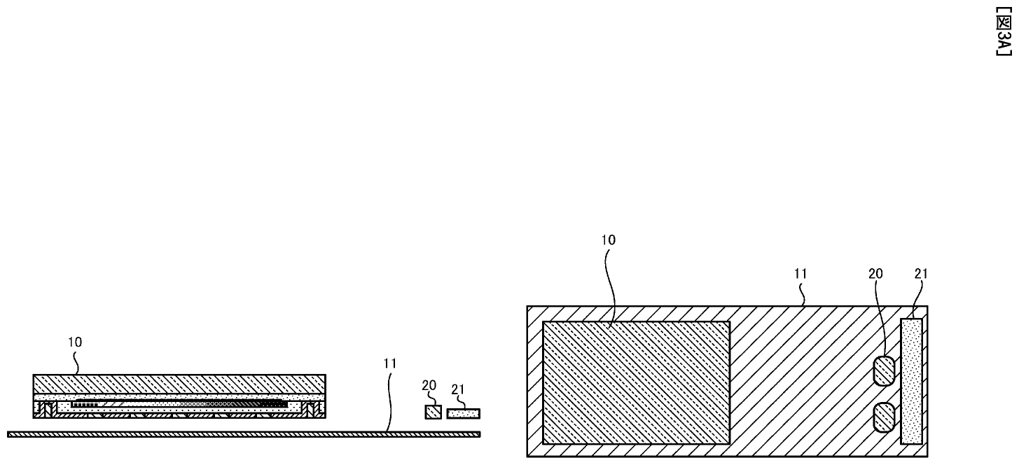

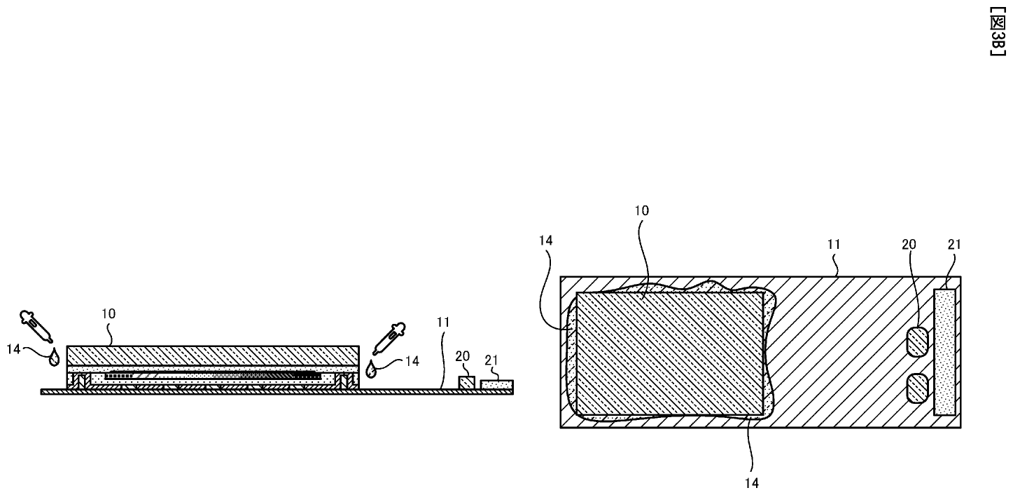

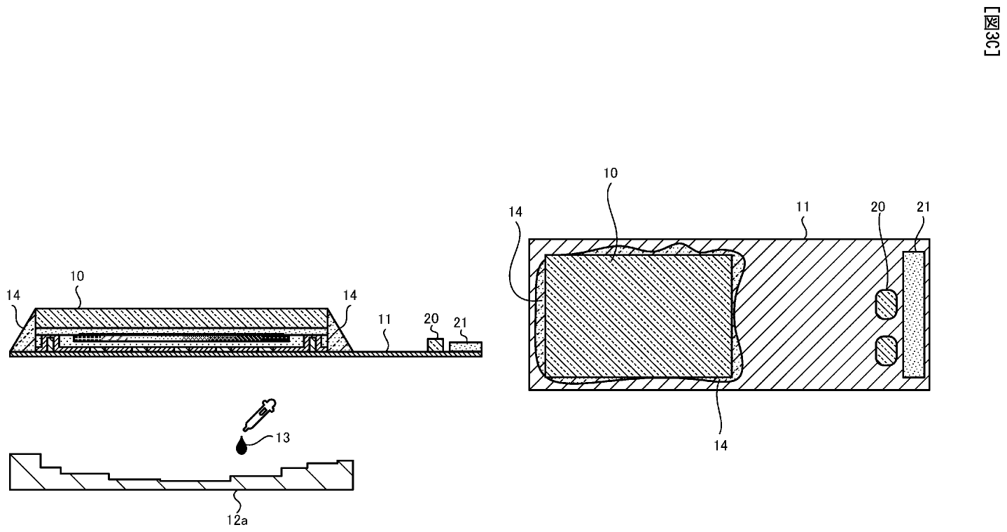

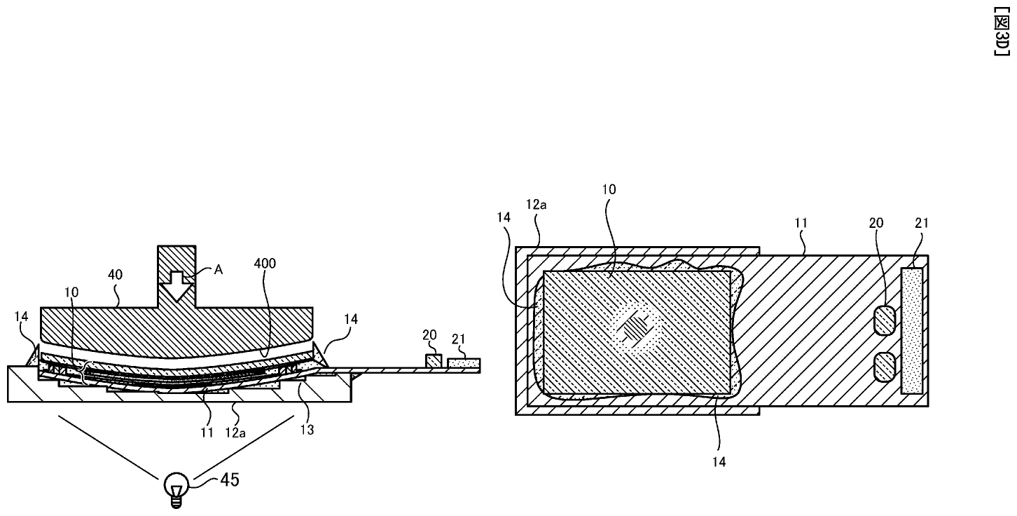

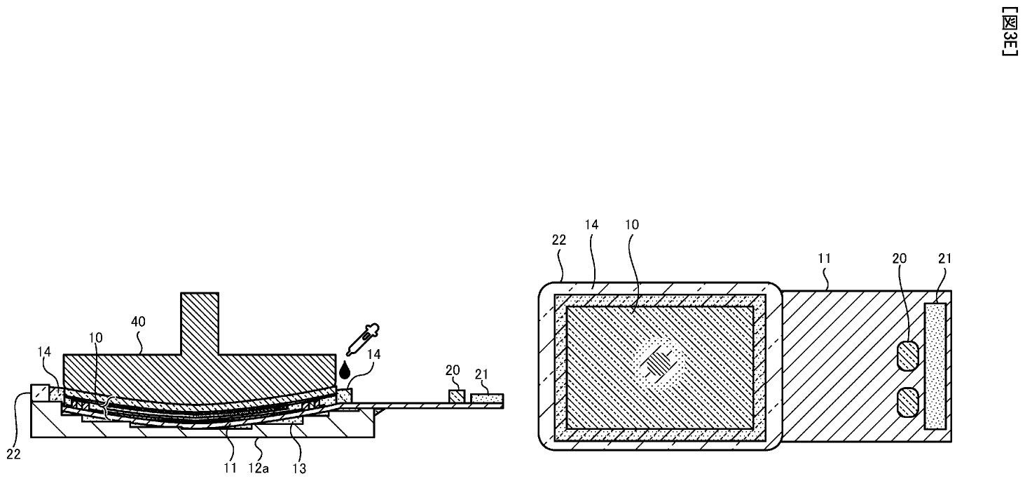

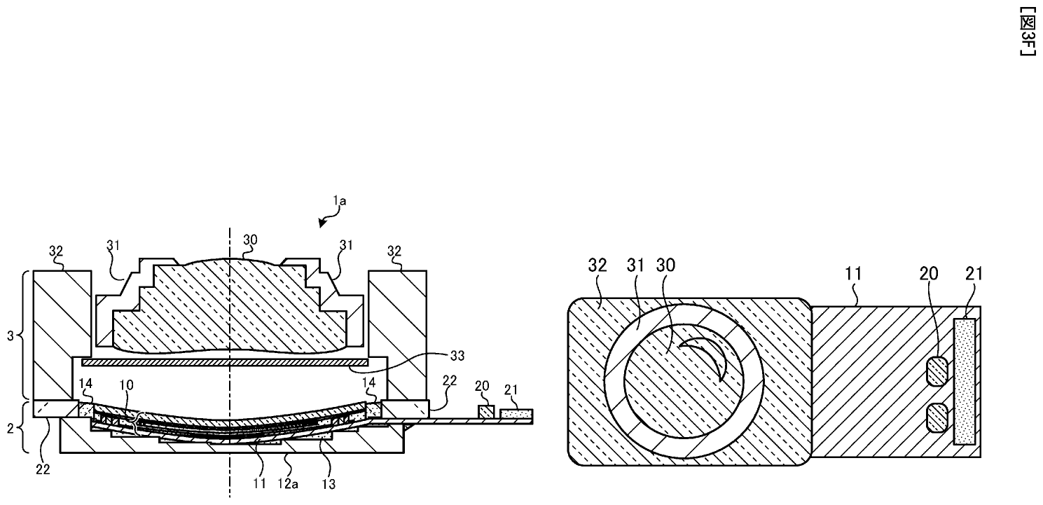

Next, a method of manufacturing an imaging device 1a according to the first embodiment will be described. FIGS. 3A to 3F are schematic diagrams for explaining a method of manufacturing the imaging element according to the first embodiment. In FIGS. 3A to 3F, a left diagram is a cross-sectional view taken along a plane including an optical axis of incident light, and a right diagram is a top view illustrating an example viewed from a light incident direction.

First, in a process illustrated in FIG. 3A, the semiconductor component 20 and the connector 21 are arranged and connected on the circuit board 11 on which the CSP solid-state imaging element 10 is mounted. Next, in a process illustrated in FIG. 3B, the CSP solid-state imaging element 10 is placed at a predetermined position on the circuit board 11. Then, the fixing agent 14 is applied around the CSP solid-state imaging element 10 so that the placed CSP solid-state imaging element 10 is not separated from the circuit board 11, and the applied fixing agent 14 is cured. As a material of the fixing agent 14, a black adhesive resin can be applied as described above, and curing types such as an ultra-violet (UV) curing type, a temperature curing type, and a time curing type are not particularly limited.

For example, after the fixing agent 14 is cured, in a process illustrated in FIG. 3C, as illustrated in the left diagram of FIG. 3C, the pedestal 12a having a seat surface molded according to a shape of the CSP solid-state imaging element 10 to be curved is disposed on a side of the circuit board 11 opposite to a side on which the CSP solid-state imaging element 10 is disposed. In this example, the pedestal 12a has a stepped recess. Then, the adhesive 13 for connecting the circuit board 11 and the pedestal 12a is applied to the seat surface of the pedestal 12a. As illustrated in the right diagram of FIG. 3C, the adhesive 13 is applied around the CSP solid-state imaging element 10. Note that, in this example, a UV curing type adhesive is used as the adhesive 13, and the pedestal 12a is configured using a material capable of transmitting light of a wavelength component in an ultraviolet region.

Next, in a process illustrated in FIG. 3D, as illustrated in the left diagram of FIG. 3D, a pushing tool 40 is pressed against the CSP solid-state imaging element 10 fixed to the circuit board 11 in FIG. 3C at a predetermined pressure from a surface side of the glass substrate 102 in the CSP solid-state imaging element 10 (indicated by an arrow A in the drawing). The right diagram of FIG. 3D illustrates the pedestal 12a protruding from the circuit board 11, but this is for illustrative purposes and is not limited to this example.

As illustrated in the left diagram of FIG. 3D, in the pushing tool 40, a pressing surface 400 to be pressed against the CSP solid-state imaging element 10 has a shape corresponding to a curved shape when the CSP solid-state imaging element 10 is curved. For example, the pressing surface 400 has a shape corresponding to a shape of the seat surface of the pedestal 12a. In this example, since the seat surface of the pedestal 12a has a stepped shape, the shape of the pressing surface 400 of the pushing tool 40 is a curved surface shape on which each edge of the stepped shape abuts.

While the pushing tool 40 is pressed against the CSP solid-state imaging element 10, UV light is emitted from a surface opposite to the seat surface of the pedestal 12a by a light source 45 to cure and fix the adhesive 13. In a state where the adhesive 13 is cured and the pedestal 12a is fixed to the circuit board 11, the CSP solid-state imaging element 10 is maintained in a suitable curved state.

Next, in a process illustrated in FIG. 3E, the spacer 22 for connection with the actuator 32 is disposed around the CSP solid-state imaging element 10 of the circuit board 11. Then, the fixing agent 14 is applied and fixed between the spacer 22 and the CSP solid-state imaging element 10 in order to reduce a flare phenomenon caused by side surface light leaking from a side surface of the glass substrate 102 in the CSP solid-state imaging element 10.

After fixing the fixing agent 14, the actuator 32 provided with the lens group 30 and the infrared cut filter 33 is attached onto the spacer 22 disposed in FIG. 3E in a process illustrated in FIG. 3F. The actuator 32 is created in advance in a process different from that in FIGS. 3A to 3E described above, for example.

Note that, in the above description, in the process of FIG. 3D, the adhesive 13 that cures by irradiation of the UV term is used in order to fix the CSP solid-state imaging element 10 to the pedestal 12a in a curved shape, but this is not limited to this example. For example, an adhesive that is cured by heat or an adhesive that is cured with time can be used as the adhesive 13. In this case, the pedestal 12a may not use a material that transmits light of a wavelength component in the ultraviolet region (a material transparent to ultraviolet rays). That is, the type of the adhesive 13 is not particularly limited as long as the CSP solid-state imaging element 10 can be fixed to the pedestal 12a while being held in a curved state.

(1-0-3. Details of Pressing Process)

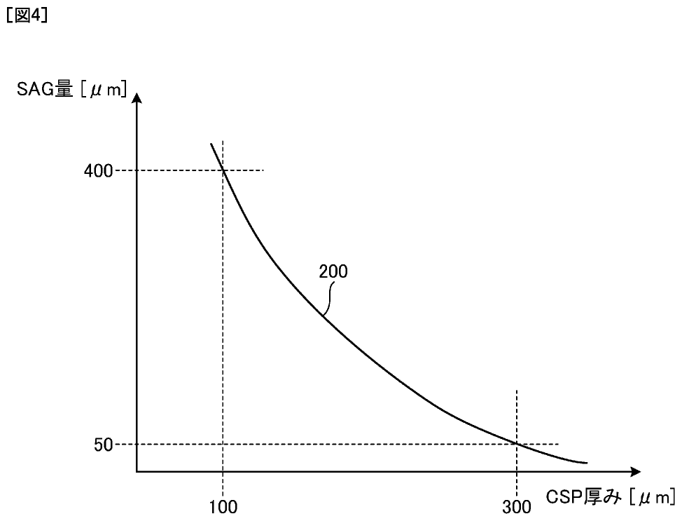

Here, the process of pressing by the pushing tool 40 described in FIG. 3D will be described in more detail. FIG. 4 is a graph illustrating an example of a relationship between a Sag amount and a thickness of the CSP solid-state imaging element 10 applicable to the first embodiment. In FIG. 4, a vertical axis represents the Sag amount, and a horizontal axis represents the thickness of the CSP solid-state imaging element 10. Note that the Sag amount indicates an amount of curvature in a Z-axis direction (optical axis direction) in a lens or the like. Here, the curvature amount of the CSP solid-state imaging element 10 is illustrated as a Sag amount. Further, FIG. 4 is a graph based on a simulation result.

In FIG. 4, a characteristic line 200 indicates a limit at which the CSP solid-state imaging element 10 is destroyed by pressing. That is, under a condition on a right side of the characteristic line 200, the CSP solid-state imaging element 10 is destroyed. As can be seen from FIG. 4, the Sag amount increases as the CSP solid-state imaging element 10 is thinner, and decreases as the CSP solid-state imaging element is thicker. In the example of FIG. 4, when the thickness of the CSP solid-state imaging element 10 is 100 [μm], the Sag amount is 400 [μm], and when the thickness is 300 [μm], the Sag amount is 50 [μm]. On the other hand, for example, in a case where the Sag amount is set to an amount exceeding 50 [μm], for example, 100 [μm] in the CSP solid-state imaging element 10 having a thickness of 300 [μm], the CSP solid-state imaging element 10 is destroyed.

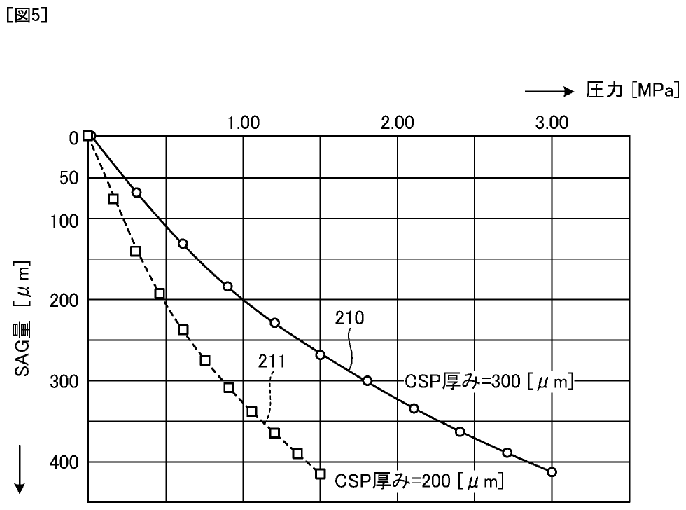

FIG. 5 is a graph illustrating an example of a relationship between a Sag amount and a pressing pressure by pressing of the pushing tool 40, which is applicable to the first embodiment. In FIG. 5, a vertical axis represents the Sag amount, and a horizontal axis represents the pressing pressure. Note that, in the vertical axis, the unit is [mm], an upper end is an origin (Sag amount=0), and the Sag amount increases as going downward. Further, in this case, the Sag amount is illustrated as a larger curvature amount as a negative value is larger. Furthermore, in the example of FIG. 5, the unit of the pressing pressure is [MPa] (megapascal). Note that FIG. 5 is a result of simulation, and destruction of the CSP solid-state imaging element 10 is not taken into consideration.

In FIG. 5, a characteristic line 210 indicates an example in which a thickness of the CSP solid-state imaging element 10 is 300 [μm], and a characteristic line 211 indicates an example in which a thickness of the CSP solid-state imaging element 10 is 300 [μm]. It can be seen that the pressing pressure for obtaining the same Sag amount is smaller when the CSP solid-state imaging element 10 is thinner.

Note that the relationships in FIGS. 4 and 5 described above vary depending on each element (thickness, material, and the like of each of the solid-state imaging element 100, the resin layer 101, and the glass substrate 102) constituting the CSP solid-state imaging element 10.

(1-0-4. Comparison With Existing Techniques)

Here, the first embodiment of the present disclosure is compared with the existing techniques (Patent Literatures 1 to 3). For example, Patent Literatures 1 and 2 disclose a method of forming a curved shape of a solid-state imaging element by drilling a suction hole in a curved pedestal and performing suction from the suction hole. According to this method, since the solid-state imaging element is sucked over a very long time so as not to be broken such as a crack, and an adhesive is fixed in a state where the curve is formed, it takes a long time to form the curved shape. Further, since the techniques described in Patent Literatures 1 and 2 are methods of sucking and mounting the solid-state imaging element, the pedestal becomes thick, and as a result, they do not greatly contribute to the height reduction of an imaging device.

Furthermore, Patent Literature 3 discloses a method of forming a curved solid-state imaging device by forming a curve by an effect of an adhesive using an adhesive such as a thermosetting resin and a support substrate formed in a curve. Here, it is known that the thermosetting resin is fixed from a periphery of the solid-state imaging element. Therefore, in the method of Patent Literature 3, when the thermosetting resin is fixed from the periphery, a thermosetting resin portion below a center of a solid-state imaging element becomes a resin reservoir, and there is a high possibility that a curved shape of the solid-state imaging device becomes a shape different from a shape of the support substrate formed based on a desired curved shape. That is, in the method of Patent Literature 3, it is difficult to form a desired curved shape of the solid-state imaging element.

On the other hand, in the imaging device 1a according to the first embodiment, the pushing tool 40 is pressed against the CSP solid-state imaging element 10 to form the curved shape of the CSP solid-state imaging element 10. Therefore, the curved shape can be formed by a relatively easy method of pressing the pushing tool 40, and the time required for forming the curved shape can be shortened. Thus, the time in manufacturing can be shortened, and the cost can be reduced.

Further, the imaging device 1a according to the first embodiment can curve the CSP solid-state imaging element 10, that is, curve the light receiving surface of the solid-state imaging element 100 included in the CSP solid-state imaging element 10, and maintain the curved state. Therefore, an opening can be enlarged without deteriorating lens performance such as distortion aberration, field curvature, and light falloff at the periphery, which are characteristics of the lens in the lens group 30.

Furthermore, in the imaging device 1a according to the first embodiment, the above-described lens performance deterioration is reduced, so that the design of the lens (the lens group 30) is facilitated, and inexpensive lenses such as reduction in the number of lens systems in the lens group 30 and reduction in the number of aspherical lenses can be adopted. Here, since an aspherical lens is expensive and has a large manufacturing variation, and the number of aspherical lenses can be reduced, it is possible to provide the imaging device 1a that is inexpensive and has good performance. Further, since the number of lenses in the lens group 30 can be reduced (for example, the number of aspherical lenses can be reduced), the height of the imaging device 1a as a whole can be reduced.

Furthermore, the pedestal 12a used in the imaging device 1a according to the first embodiment is used to hold the curved state of the CSP solid-state imaging element 10, and it is not necessary to drill suction holes as in the configurations described in Patent Literatures 1 and 2. Therefore, the pedestal 12a can be configured to be thin, whereby the height can also be reduced, and the cost can also be reduced.

(1-0-5. Other Shapes of Pedestal)

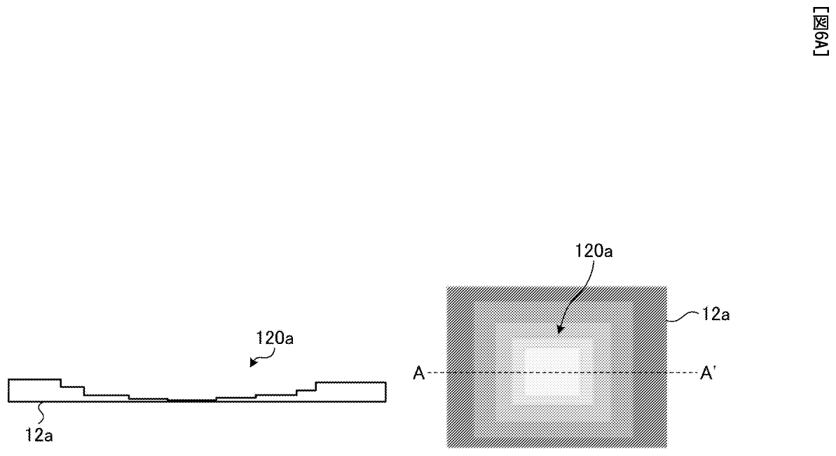

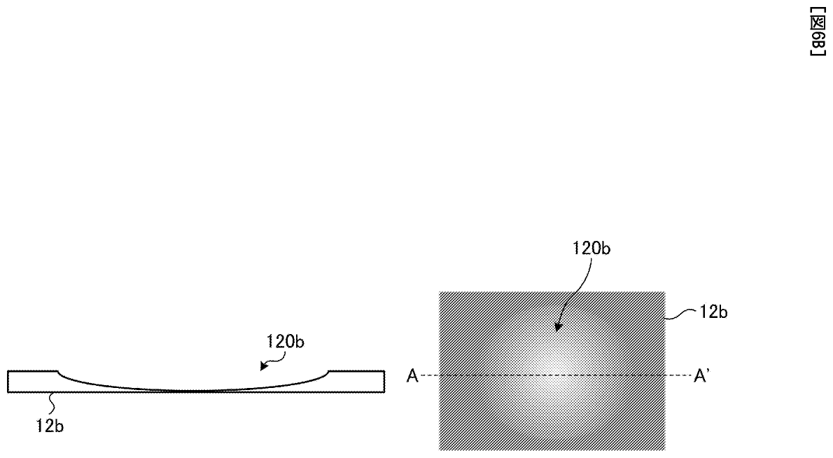

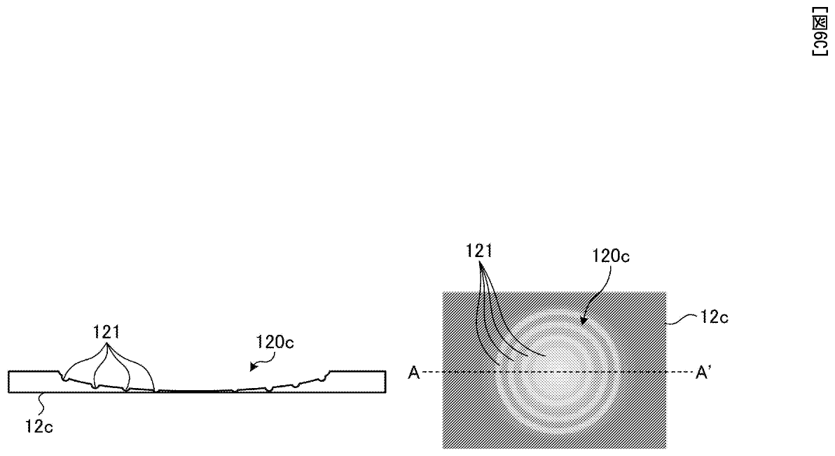

In the above description, it has been described that the seat surface of the pedestal 12a has a step-shaped recess, but this is not limited to this example. Examples of the shape of the seat surface of the pedestal applicable to the first embodiment will be described with reference to FIGS. 6A, 6B, and 6C. In each of FIGS. 6A, 6B, and 6C, a left diagram is a cross-sectional view taken along a plane A-A′ including an optical axis of incident light, and a right diagram is a top view illustrating an example viewed from an incident direction of the light.

FIG. 6A is a schematic diagram illustrating a first example of a pedestal shape applicable to the first embodiment. FIG. 6A illustrates the pedestal 12a having a stepped recess 120a on the seat surface, which is illustrated in FIG. 1 and the like. The curved CSP solid-state imaging element 10 (and the circuit board 11) is held at a stepped edge portion. The stepped gap from the circuit board 11 serves as a resin reservoir for the adhesive 13. Further, in this example, the recess 120a is formed in a rectangular shape, but this is not limited to this example, and a stepped shape may be formed concentrically to form the recess 120a.

FIG. 6B is a schematic diagram illustrating a second example of the pedestal shape applicable to the first embodiment. A pedestal 12b illustrated in FIG. 6B includes a recess 120b having a curved surface shape in which the seat surface has one vertex. The curved surface shape of the recess 120b is, for example, a shape corresponding to the correction of the lens group 30, and can correspond to, for example, a shape of a convex portion of the pushing tool 40.

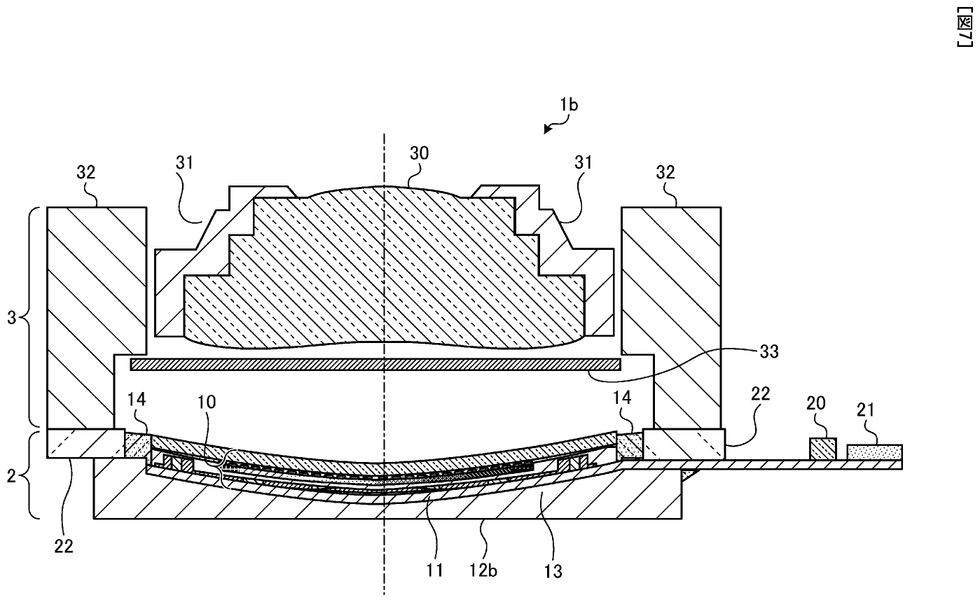

FIG. 7 is a cross-sectional view illustrating an example of a structure of the imaging device in a case where the pedestal-shaped pedestal 12b of the second example according to the first embodiment is used. In an imaging device 1b illustrated in FIG. 7, a resin reservoir for the adhesive 13 is not formed between the pedestal 12b and the circuit board 11. Therefore, depending on a type and an amount of the adhesive 13 to be used, the adhesive 13 may leak out of the recess 120b. On the other hand, by appropriately selecting the type of the adhesive 13, a device for applying the adhesive 13, and the like, and controlling an application amount, for example, the amount of the adhesive 13 to be used can be saved.

FIG. 6C is a schematic diagram illustrating a third example of the pedestal shape applicable to the first embodiment. A pedestal 12c illustrated in FIG. 6C is an example in which resin reservoirs 121 are provided in the recess 120b of the pedestal 12b illustrated in FIG. 6B. In the example of FIG. 6C, the resin reservoirs 121 are provided as grooves with respect to a recess 120c. As described above, since the resin reservoirs 121 are provided in the pedestal 12c illustrated in the third example with respect to the recess 120c formed by the curved surface having one vertex, leakage of the adhesive 13 to the outside of the recess 120c is prevented.

Note that, in the example of FIG. 6C, the resin reservoirs 121 are concentrically provided, but this is not limited to this example. For example, the resin reservoirs 121 may be provided in another shape such as a cross shape, a spiral shape, or a lattice shape.

(1-1. First Modification Example)

Next, a first modification example of the first embodiment will be described. In the first embodiment described above, the curved shape of the CSP solid-state imaging element 10 is a curved surface shape having one vertex. On the other hand, in the first modification example of the first embodiment, the curved shape of the CSP solid-state imaging element 10 is a curved shape having an extreme value.

That is, as described above, the lens disposed at a position closest to the CSP solid-state imaging element 10 in the lens group 30 in the imaging device 1a illustrated in FIG. 1 is an aspherical lens in which the image surface has a curved surface shape with an extreme value. In the first modification example of the first embodiment, the CSP solid-state imaging element 10 is curved into a curved shape having an extreme value corresponding to the shape of the lens.

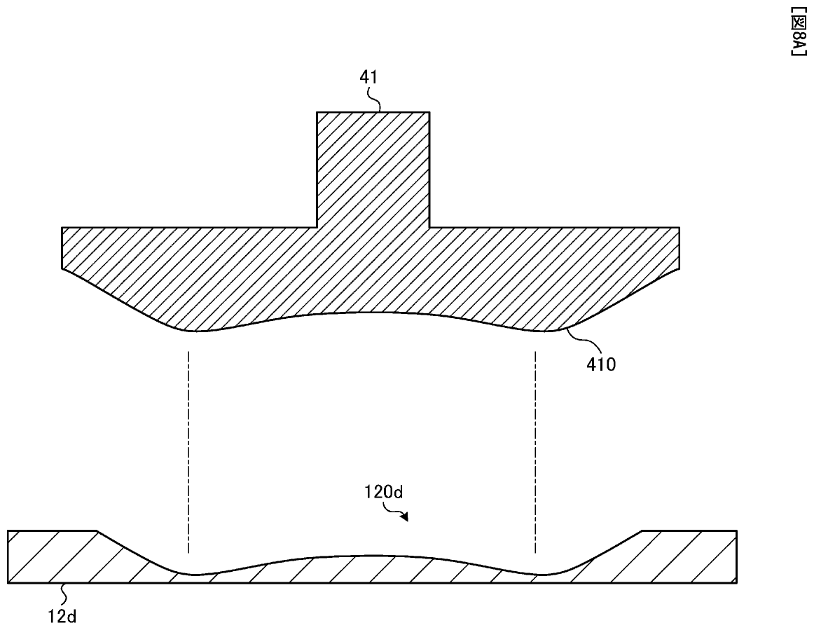

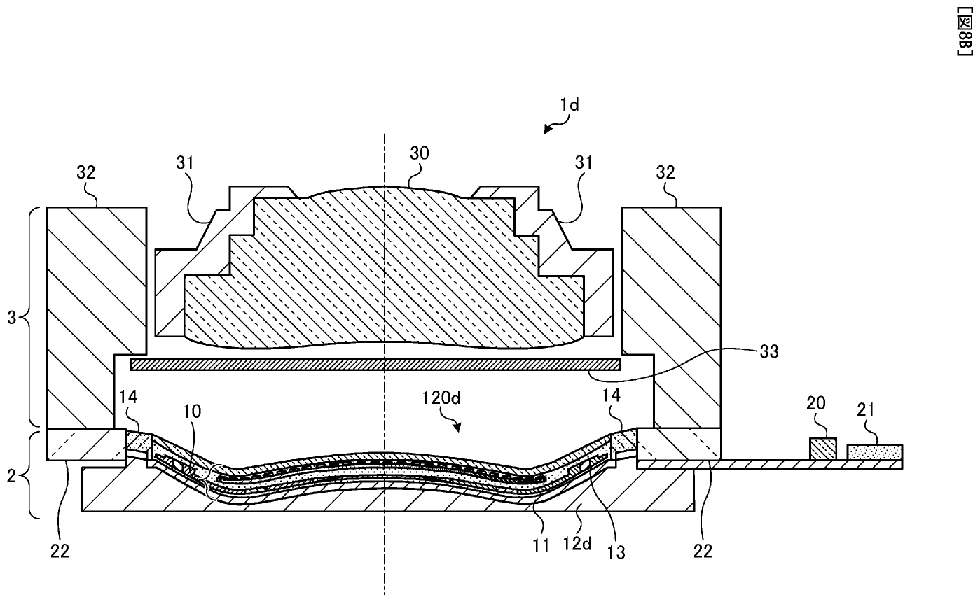

FIGS. 8A and 8B are schematic diagrams for explaining an imaging device according to the first modification example of the first embodiment. FIG. 8A is a schematic view illustrating an example of a pushing tool according to the first modification example of the first embodiment. An upper view of FIG. 8A is a schematic cross-sectional view of a pushing tool 41 according to the first modification example of the first embodiment, and a lower view is a schematic cross-sectional view of a pedestal 12d corresponding to the pushing tool 41. In FIG. 8A, a pressing surface 410 of the pushing tool 41 corresponds to a shape of an image surface of the lens disposed at the position closest to the CSP solid-state imaging element 10 of the lens group 30 in the imaging device 1a illustrated in FIG. 1, and has a curved shape having an extreme value. Further, a seat surface of the pedestal 12d also corresponds to a shape of the pressing surface 410 and has a recess 120d formed by a curved surface having an extreme value. Note that here, the resin reservoir provided in the pedestal 12d is omitted.

By executing the respective processes illustrated in FIGS. 3A to 3F using the pushing tool 41 and the pedestal 12d, the CSP solid-state imaging element 10 can be curved into an aspherical curved shape corresponding to the pressing surface 410 of the pushing tool 41 and the recess 120d of the pedestal 12d. FIG. 8B is a cross-sectional view illustrating an example of a structure of the imaging device 1d on which the CSP solid-state imaging element 10 curved in an aspherical shape by the pushing tool 41 in FIG. 8A is mounted.

By curving the CSP solid-state imaging element 10 in an aspherical shape in this manner, aberration of the lens can be reduced by a combination of the lens group 30 included in the imaging device 1d and the CSP solid-state imaging element 10, and this can contribute to height reduction of the imaging device 1d. Note that, in the first modification example of the first embodiment, the curved shape of the CSP solid-state imaging element 10 is not limited to the curved surface having the above-described extreme value, and can be applied to other curved surface shapes such as a free-form surface.

(1-2. Second Modification Example)

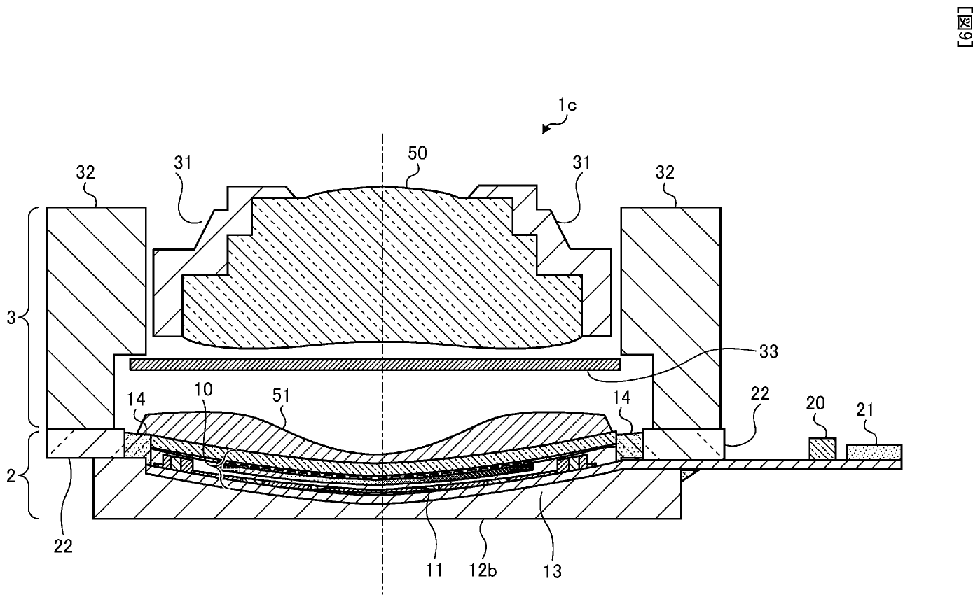

Next, a second modification example of the first embodiment will be described. FIG. 9 is a cross-sectional view illustrating an example of a structure of an imaging element according to the second modification example of the first embodiment. In FIG. 9, an imaging device 1c according to the second modification example of the first embodiment is an example in which lenses included in the lens group 30 illustrated in FIG. 1 are divided into two groups of a lowermost lens and other lenses, and the lowermost lens 51 is mounted as, for example, a wafer level lens on the curved CSP solid-state imaging element 10.

A method for forming the lens 51 will be schematically described. First, the CSP solid-state imaging element 10 is curved in accordance with the pedestal 12b by each process described with reference to FIGS. 3A to 3F. Note that here, the pedestal 12b illustrated in FIG. 6B is used as a pedestal, but this is not limited to this example, and the pedestal 12a illustrated in FIG. 6A or the pedestal 12c illustrated in FIG. 6C may be used.

In the next process, a material of the lens 51 is put on the glass substrate 102 of the CSP solid-state imaging element 10. As the material of the lens 51, for example, a resin that is cured by UV light, heat, time, or the like and transmits light of a wavelength component in a visible light region after curing can be applied. Here, a UV curing type resin that is cured by UV light is used.

In the next process, a stamp mold having a shape corresponding to a shape on an incident surface side of the lens 51 is pressed against the material of the lens 51 put on the lens 51, and the material is formed into the shape of the lens 51. Here, it is assumed that the stamp mold can transmit UV light.

In the next process, the material of the lens 51 pressed with the stamp mold is irradiated with UV light, for example, from above the mold, and the material is cured. After the material is cured to form the lens 51, the stamp mold is removed. As a result, the lens 51 is formed on the CSP solid-state imaging element 10.

As described above, the lowermost lens 51 included in the lens group 30 is separated from the lens group 30 and mounted on the curved CSP solid-state imaging element 10, whereby the lens group 30 can be downsized and the height of the imaging device 1c can be reduced as a whole.

### 2. Second Embodiment

Next, a second embodiment of the present disclosure will be described. The second embodiment is an example in which any of the imaging devices 1a to 1c according to the first embodiment and the modification examples thereof described above is applied to an electronic device. Hereinafter, an example in which the imaging device 1a is applied will be described unless otherwise specified.

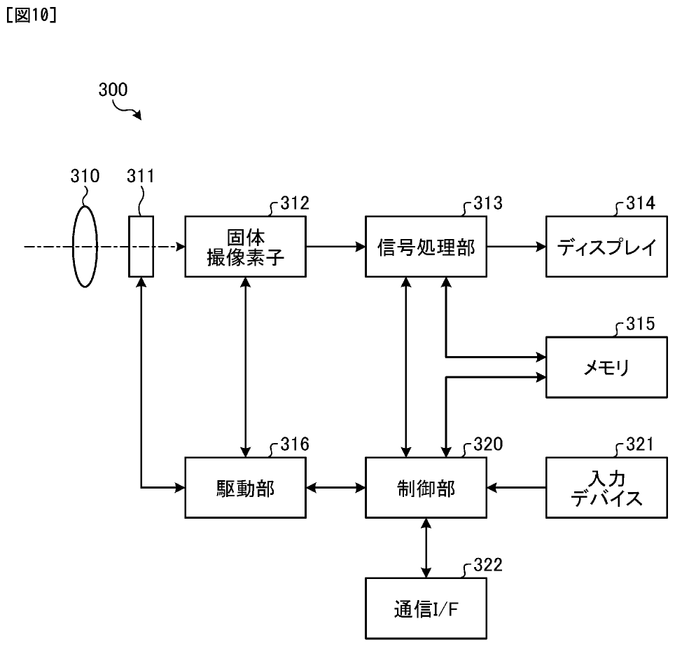

FIG. 10 is a block diagram illustrating a configuration of an example of a terminal device 300 as an electronic device applicable to the second embodiment. The terminal device 300 is, for example, a multifunctional mobile phone terminal (smartphone), and has an imaging function. The terminal device 300 may be another electronic device such as a tablet personal computer as long as the electronic device has an imaging function and is configured to be easily carried.

In the example of FIG. 10, the terminal device 300 includes an optical system 310, an optical driving device 311, a solid-state imaging element 312, a signal processing unit 313, a display 314, a memory 315, and a drive unit 316. The terminal device 300 further includes a control unit 320, an input device 321, and a communication I/F 322.

The control unit 320 includes a central processing unit (CPU), a read only memory (ROM), and a random access memory (RAM). The control unit 320 controls an entire operation of the terminal device 300 by the CPU operating using the RAM as a work memory according to a program stored in advance in the ROM. The input device 321 receives a user operation and transmits a control signal corresponding to the received user operation to the control unit 320. The communication I/F 322 communicates with the outside by, for example, wireless communication according to a predetermined protocol under the control of the control unit 320.

The optical system 310 corresponds to the lens group 30 described above, includes one or a plurality of lenses, guides light (incident light) from a subject to the solid-state imaging element 312, and forms an image on a light receiving surface of the solid-state imaging element 312. The optical driving device 311 includes a shutter unit and the actuator 32 described above. In the optical driving device 311, the shutter unit is disposed between the optical system 310 and the solid-state imaging element 312, and controls a light irradiation period and a light shielding period with respect to the solid-state imaging element 312 according to the control of the control unit 320. Further, The actuator 32 executes an autofocus operation and a camera shake correction operation under the control of the control unit 320.

The solid-state imaging element 312 corresponds to the CSP solid-state imaging element 10 described above, and accumulates signal charges for a certain period of time in accordance with light that forms an image on the light receiving surface of the solid-state imaging element 100 via the optical system 310 and the shutter unit of the optical driving device 311. The signal charges accumulated in the solid-state imaging element 312 are transferred in accordance with a drive signal (timing signal) supplied from the drive unit 316.

Under the control of the control unit 320, the drive unit 316 outputs a drive signal for controlling a transfer operation of the solid-state imaging element 312 and a shutter operation of the shutter unit in the optical driving device 311 to drive the solid-state imaging element 312 and the shutter unit.

Under the control of the control unit 320, the signal processing unit 313 performs various types of signal processing such as CDS on the signal charges output from the solid-state imaging element 312, and generates image data according to the signal charges. Furthermore, the signal processing unit 313 can display image data obtained by performing signal processing on the display 314 and store the image data in the memory 315 under the control of the control unit 320.

The control unit 320 can transmit the image data stored in the memory 315 to the outside by the communication I/F 322 according to a user operation on the input device 321.

In the terminal device 300 configured as described above, by applying the above-described imaging device 1a (alternatively, the imaging device 1b or 1c) as the optical system 310 and the solid-state imaging element 312, it is possible to increase the size of the opening without deteriorating lens performance such as distortion aberration, field curvature, and light falloff at the periphery, which are characteristics of the lens in the lens group 30, and to improve the image quality of the image data.

Further, since the number of lenses in the lens group 30 can be reduced (for example, the number of aspherical lenses can be reduced) by curving the CSP solid-state imaging element 10, it is possible to reduce the overall height in the imaging device 1a (alternatively, the imaging device 1b or 1c). Furthermore, since the curved shape of the CSP solid-state imaging element 10 is formed by pressing the pushing tool 40 against the CSP solid-state imaging element 10, the cost can also be reduced.

### 3. Third Embodiment

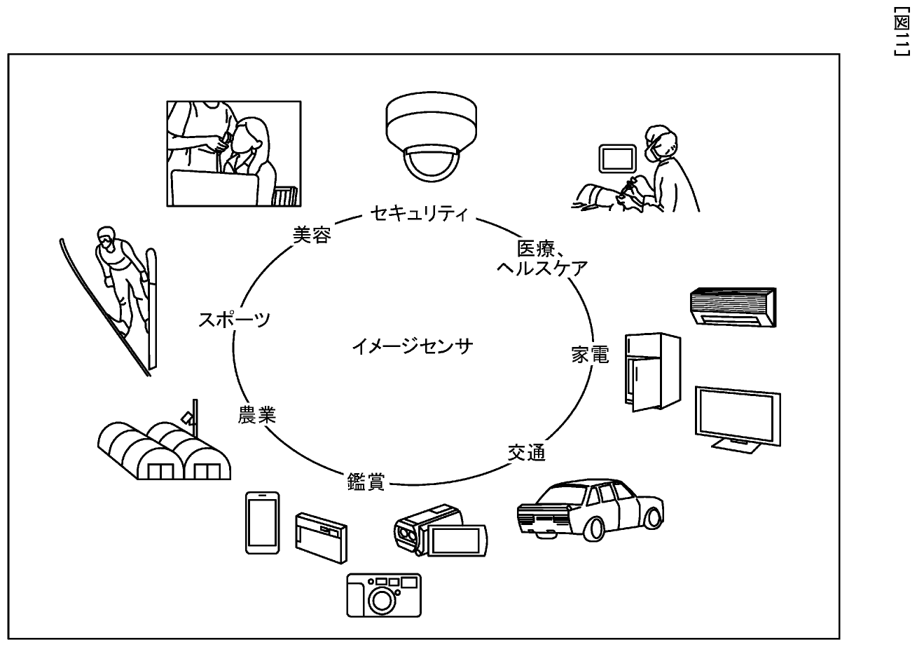

Next, as a third embodiment, application examples of the imaging devices 1a to 1c according to the first embodiment and the respective modification examples thereof according to the present disclosure will be described. FIG. 11 is a diagram illustrating usage examples of the imaging devices 1a to 1c according to the above-described first embodiment and the respective modification examples thereof.

The imaging devices 1a to 1c described above can be used, for example, in various cases of sensing light such as visible light, infrared light, ultraviolet light, and X-rays as follows.

A device that captures an image to be used for viewing, such as a digital camera or a portable device with a camera function.

A device used for traffic, such as an in-vehicle sensor that captures images of the front, rear, surroundings, inside, and the like of an automobile for safe driving such as automatic stop, recognition of a driver's condition, and the like, a monitoring camera that monitors traveling vehicles and roads, and a distance measuring sensor that measures a distance between vehicles and the like.

A device used for home appliances such as a TV, a refrigerator, and an air conditioner in order to capture an image of a gesture of a user and operate the device according to the gesture.

A device used for medical care or healthcare, such as an endoscope or a device that performs angiography by receiving infrared light.

A device used for security, such as a monitoring camera for crime prevention or a camera for person authentication.

A device used for beauty care, such as a skin measuring instrument for photographing skin or a microscope for photographing a scalp.

An apparatus used for sports, such as an action camera or a wearable camera for sports or the like.

A device used for agriculture, such as a camera for monitoring conditions of fields and crops.

### Further Application Example of Technique According to Present Disclosure (3-1. Application Example to Endoscopic Surgery System)

The technique according to the present disclosure (the present technique) can be applied to various products. For example, the technique according to the present disclosure may be applied to an endoscopic surgical system.

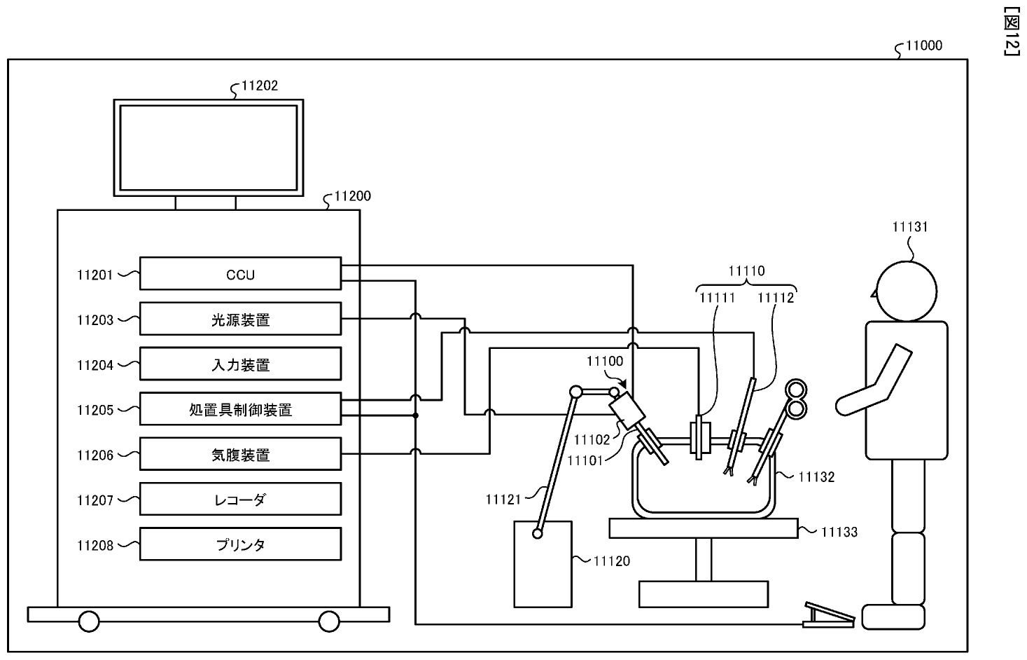

FIG. 12 is a diagram illustrating an example of a schematic configuration of an endoscopic surgery system to which the technique according to the present disclosure (the present technique) can be applied.

FIG. 12 illustrates a state in which an operator (doctor) 11131 is performing surgery on a patient 11132 on a patient bed 11133 using an endoscopic surgery system 11000. As illustrated, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens barrel 11101 whose region of a predetermined length from a distal end is inserted into a body cavity of the patient 11132, and a camera head 11102 connected to a proximal end of the lens barrel 11101. In the illustrated example, the endoscope 11100 configured as a so-called rigid scope having the rigid lens barrel 11101 is illustrated, but the endoscope 11100 may be configured as a so-called flexible scope having a flexible lens barrel.

An opening portion into which an objective lens is fitted is provided at the distal end of the lens barrel 11101. A light source device 11203 is connected to the endoscope 11100, and light generated by the light source device 11203 is guided to the distal end of the lens barrel by a light guide extending inside the lens barrel 11101, and is emitted toward an observation target in the body cavity of the patient 11132 via the objective lens. Note that the endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electric signal corresponding to the observation light, that is, an image signal corresponding to the observation image is generated. The image signal is transmitted to a camera control unit (CCU) 11201 as RAW data.

The CCU 11201 includes a central processing unit (CPU), a graphics processing unit (GPU), and the like, and integrally controls operation of the endoscope 11100 and a display device 11202. Furthermore, the CCU 11201 receives an image signal from the camera head 11102, and performs various types of image processing for displaying an image based on the image signal, such as development processing (demosaic processing), on the image signal.

The display device 11202 displays an image based on the image signal subjected to the image processing by the CCU 11201 under the control of the CCU 11201.

The light source device 11203 includes a light source such as a light emitting diode (LED), for example, and supplies irradiation light for imaging a surgical site or the like to the endoscope 11100.

An input device 11204 is an input interface for the endoscopic surgery system 11000. The user can input various types of information and instructions to the endoscopic surgery system 11000 via the input device 11204. For example, the user inputs an instruction or the like to change imaging conditions (type, magnification, focal length, and the like of irradiation light) by the endoscope 11100.

A treatment tool control device 11205 controls driving of the energy treatment tool 11112 for cauterization and incision of tissue, sealing of a blood vessel, or the like. A pneumoperitoneum device 11206 feeds gas into the body cavity of the patient 11132 via the pneumoperitoneum tube 11111 in order to inflate the body cavity for the purpose of securing a visual field by the endoscope 11100 and securing a working space of the operator. A recorder 11207 is a device capable of recording various types of information regarding surgery. A printer 11208 is a device capable of printing various types of information regarding surgery in various formats such as text, image, or graph.

Note that the light source device 11203 that supplies the endoscope 11100 with the irradiation light at the time of imaging the surgical site can include, for example, an LED, a laser light source, or a white light source including a combination thereof. In a case where the white light source includes a combination of RGB laser light sources, since the output intensity and the output timing of each color (each wavelength) can be controlled with high accuracy, adjustment of the white balance of the captured image can be performed in the light source device 11203. Furthermore, in this case, by irradiating the observation target with the laser light from each of the RGB laser light sources in a time division manner and controlling the driving of the imaging element of the camera head 11102 in synchronization with the irradiation timing, it is also possible to capture an image corresponding to each of RGB in a time division manner. According to this method, a color image can be obtained without providing a color filter in the imaging element.

Further, the driving of the light source device 11203 may be controlled so as to change the intensity of light to be output every predetermined time. By controlling the driving of the imaging element of the camera head 11102 in synchronization with the timing of the change of the light intensity to acquire images in a time division manner and synthesizing the images, it is possible to generate an image of a high dynamic range without so-called a black fullness and halation.

Furthermore, the light source device 11203 may be configured to be able to supply light in a predetermined wavelength band corresponding to special light observation. In the special light observation, for example, so-called narrow band imaging is performed in which a predetermined tissue such as a blood vessel in a mucosal surface layer is imaged with high contrast by irradiating light in a narrower band than irradiation light (that is, white light) at the time of normal observation using wavelength dependency of light absorption in a body tissue. Alternatively, in the special light observation, fluorescence observation for obtaining an image by fluorescence generated by irradiation with excitation light may be performed. In the fluorescence observation, it is possible to irradiate a body tissue with excitation light to observe fluorescence from the body tissue (autofluorescence observation), or to locally inject a reagent such as indocyanine green (ICG) into a body tissue and irradiate the body tissue with excitation light corresponding to a fluorescence wavelength of the reagent to obtain a fluorescent image, for example. The light source device 11203 can be configured to be able to supply narrow band light and/or excitation light corresponding to such special light observation.

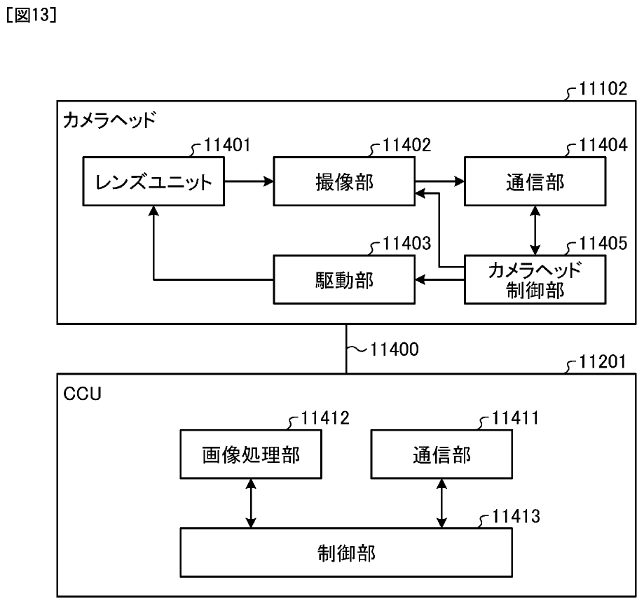

FIG. 13 is a block diagram illustrating an example of functional configurations of the camera head 11102 and the CCU 11201 illustrated in FIG. 12.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at a connection portion with the lens barrel 11101. Observation light taken in from the distal end of the lens barrel 11101 is guided to the camera head 11102, and enters the lens unit 11401. The lens unit 11401 is configured by combining a plurality of lenses including a zoom lens and a focus lens.

The imaging unit 11402 includes an imaging element. The number of imaging elements constituting the imaging unit 11402 may be one (so-called single-plate type) or a plurality of (so-called multi-plate type). In a case where the imaging unit 11402 is configured as a multi-plate type, for example, image signals corresponding to RGB may be generated by the respective imaging elements, and a color image may be obtained by combining the image signals. Alternatively, the imaging unit 11402 may include a pair of imaging elements for acquiring right-eye and left-eye image signals corresponding to three-dimensional (3D) display. By performing the 3D display, the operator 11131 can more accurately grasp a depth of a living tissue in the surgical site. Note that, in a case where the imaging unit 11402 is configured as the multi-plate type, a plurality of lens units 11401 can be provided corresponding to the respective imaging elements.

Further, the imaging unit 11402 is not necessarily provided in the camera head 11102. For example, the imaging unit 11402 may be provided immediately after the objective lens inside the lens barrel 11101.

The drive unit 11403 includes an actuator, and moves the zoom lens and the focus lens of the lens unit 11401 by a predetermined distance along the optical axis under the control of the camera head control unit 11405. As a result, the magnification and focus of the image captured by the imaging unit 11402 can be appropriately adjusted.

The communication unit 11404 includes a communication device for transmitting and receiving various types of information to and from the CCU 11201. The communication unit 11404 transmits the image signal obtained from the imaging unit 11402 as RAW data to the CCU 11201 via the transmission cable 11400.

Furthermore, the communication unit 11404 receives a control signal for controlling driving of the camera head 11102 from the CCU 11201, and supplies the control signal to the camera head control unit 11405. The control signal includes, for example, information regarding imaging conditions such as information for specifying a frame rate of a captured image, information for specifying an exposure value at the time of imaging, and/or information for specifying a magnification and a focus of a captured image.

Note that the imaging conditions such as the frame rate, the exposure value, the magnification, and the focus may be appropriately specified by the user, or may be automatically set by the control unit 11413 of the CCU 11201 on the basis of the acquired image signal. In the latter case, a so-called auto exposure (AE) function, an auto focus (AF) function, and an auto white balance (AWB) function are installed in the endoscope 11100.

The camera head control unit 11405 controls driving of the camera head 11102 on the basis of the control signal from the CCU 11201 received via the communication unit 11404.

The communication unit 11411 includes a communication device for transmitting and receiving various types of information to and from the camera head 11102. The communication unit 11411 receives an image signal transmitted from the camera head 11102 via the transmission cable 11400.

Further, the communication unit 11411 transmits a control signal for controlling driving of the camera head 11102 to the camera head 11102. The image signal and the control signal can be transmitted by electric communication, optical communication, or the like.

The image processing unit 11412 performs various types of image processing on the image signal that is RAW data transmitted from the camera head 11102.

The control unit 11413 performs various types of control related to imaging of a surgical site or the like by the endoscope 11100 and display of a captured image obtained by imaging of the surgical site or the like. For example, the control unit 11413 generates a control signal for controlling driving of the camera head 11102.

Furthermore, the control unit 11413 causes the display device 11202 to display a captured image of a surgical site or the like on the basis of the image signal subjected to the image processing by the image processing unit 11412. At this time, the control unit 11413 may recognize various objects in the captured image using various image recognition technologies. For example, the control unit 11413 can recognize a surgical tool such as forceps, a specific body part, bleeding, mist at the time of using the energy treatment tool 11112, and the like by detecting the shape, color, and the like of an edge of an object included in the captured image. When displaying the captured image on the display device 11202, the control unit 11413 may superimpose and display various types of surgery support information on the image of the surgical site by using the recognition result. Since the surgery support information is superimposed and displayed and presented to the operator 11131, the burden on the operator 11131 can be reduced and the operator 11131 can reliably proceed with the surgery.

The transmission cable 11400 connecting the camera head 11102 and the CCU 11201 is an electric signal cable compatible with electric signal communication, an optical fiber compatible with optical communication, or a composite cable thereof.

Here, in the illustrated example, communication is performed by wire using the transmission cable 11400, but communication between the camera head 11102 and the CCU 11201 may be performed wirelessly.

An example of the endoscopic surgery system to which the technique according to the present disclosure can be applied has been described above. The technique according to the present disclosure can be applied to, for example, the lens unit 11401, the imaging unit 11402, and the like of the camera head 11102 among the above-described configurations. As a result, a clearer image of the operation site can be obtained, so that the operator can reliably confirm the operation site. Furthermore, since the height can be reduced with respect to the existing configuration, the endoscope 11100 can be further downsized. Furthermore, since the structure for this is formed by applying pressure to the CSP solid-state imaging element 10 by the pushing tool 40, cost can be reduced.

(3-2. Application Example to Mobile Body)

The technique according to the present disclosure can be further applied to various products. For example, the technique according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

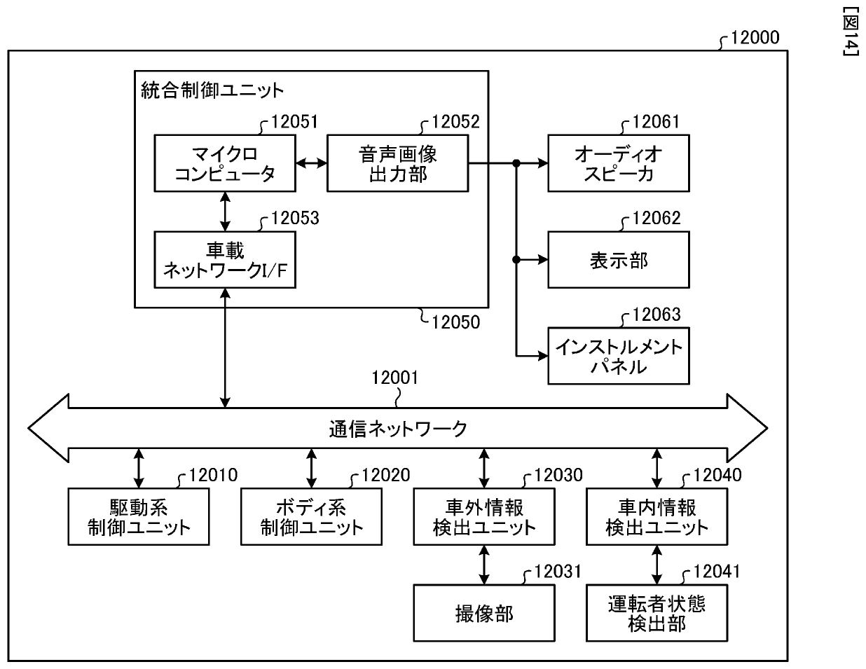

FIG. 14 is a block diagram illustrating a schematic configuration example of a vehicle control system which is an example of a moving body control system to which the technique according to the present disclosure can be applied.

A vehicle control system 12000 includes a plurality of electronic control units connected via a communication network 12001. In the example illustrated in FIG. 14, the vehicle control system 12000 includes a drive system control unit 12010, a body system control unit 12020, a vehicle exterior information detection unit 12030, a vehicle interior information detection unit 12040, and an integrated control unit 12050. Further, as a functional configuration of the integrated control unit 12050, a microcomputer 12051, an audio image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device of a driving force generation device for generating a driving force of the vehicle such as an internal combustion engine or a driving motor, a driving force transmission mechanism for transmitting the driving force to wheels, a steering mechanism for adjusting a steering angle of the vehicle, a braking device for generating a braking force of the vehicle, and the like.

The body system control unit 12020 controls operations of various devices mounted on the vehicle body according to various programs. For example, the body system control unit 12020 functions as a control device of a keyless entry system, a smart key system, a power window device, or various lamps such as a head lamp, a back lamp, a brake lamp, a blinker, or a fog lamp. In this case, radio waves or signals of various switches transmitted from a portable device that substitutes for a key can be input to the body system control unit 12020. The body system control unit 12020 receives input of these radio waves or signals, and controls a door lock device, a power window device, a lamp, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle, and receives the captured image. The vehicle exterior information detection unit 12030 may perform object detection processing or distance detection processing of a person, a vehicle, an obstacle, a sign, a character on a road surface, or the like on the basis of the received image.

The imaging unit 12031 is an optical sensor that receives light and outputs an electric signal corresponding to an amount of the received light. The imaging unit 12031 can output the electric signal as an image or can output the electric signal as distance measurement information. Further, the light received by the imaging unit 12031 may be visible light or invisible light such as infrared rays.

The vehicle interior information detection unit 12040 detects information inside the vehicle. For example, a driver state detection unit 12041 that detects a state of a driver is connected to the vehicle interior information detection unit 12040. The driver state detection unit 12041 includes, for example, a camera that images the driver, and the vehicle interior information detection unit 12040 may calculate the degree of fatigue or the degree of concentration of the driver or may determine whether or not the driver is dozing off on the basis of detection information input from the driver state detection unit 12041.

The microcomputer 12051 can calculate a control target value of the driving force generation device, the steering mechanism, or the braking device on the basis of the information inside and outside the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an advanced driver assistance system (ADAS) including collision avoidance or impact mitigation of the vehicle, follow-up traveling based on an inter-vehicle distance, vehicle speed maintenance traveling, vehicle collision warning, vehicle lane departure warning, or the like.

Furthermore, the microcomputer 12051 controls the driving force generation device, the steering mechanism, the braking device, or the like on the basis of the information around the vehicle acquired by the vehicle exterior information detection unit 12030 or the vehicle interior information detection unit 12040, thereby performing cooperative control for the purpose of automatic driving or the like in which the vehicle autonomously travels without depending on the operation of the driver.

Furthermore, the microcomputer 12051 can output a control command to the body system control unit 12020 on the basis of the vehicle exterior information acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio image output unit 12052 transmits an output signal of at least one of audio or an image to an output device capable of visually or audibly notifying an occupant of the vehicle or the outside of the vehicle of information. In the example of FIG. 14, an audio speaker 12061, a display unit 12062, and an instrument panel 12063 are illustrated as the output device. The display unit 12062 may include, for example, at least one of an on-board display and a head-up display.

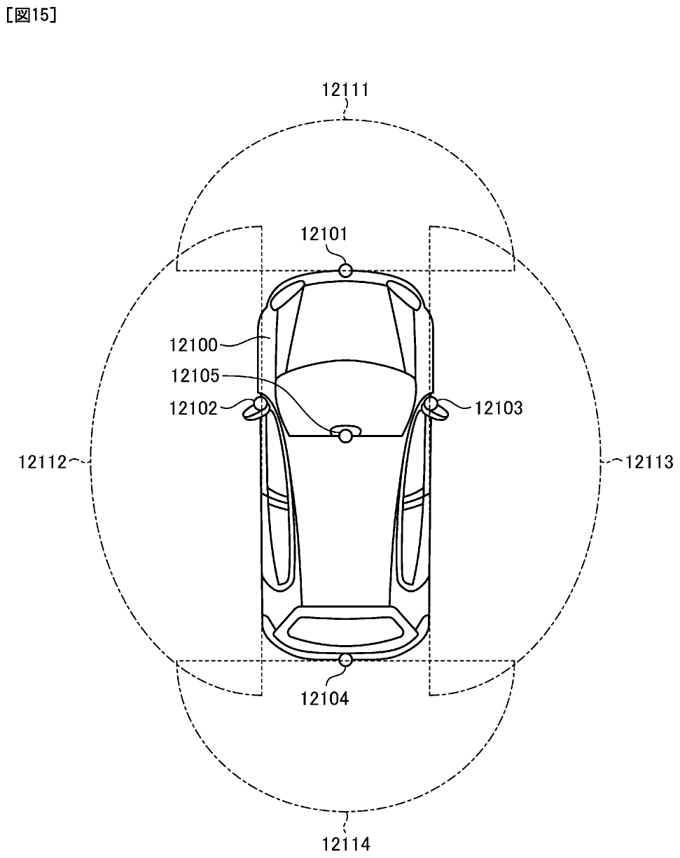

FIG. 15 is a diagram illustrating an example of an installation position of the imaging unit 12031.

In FIG. 15, a vehicle 12100 includes imaging units 12101, 12102, 12103, 12104, and 12105 as the imaging unit 12031.

The imaging units 12101, 12102, 12103, 12104, and 12105 are provided, for example, at positions such as a front nose, a side mirror, a rear bumper, a back door, and an upper portion of a windshield in a vehicle interior of the vehicle 12100. The imaging unit 12101 provided at the front nose and the imaging unit 12105 provided at the upper portion of the windshield in the vehicle interior mainly acquire images in front of the vehicle 12100. The imaging units 12102 and 12103 provided at the side mirrors mainly acquire images of the sides of the vehicle 12100. The imaging unit 12104 provided on the rear bumper or the back door mainly acquires an image behind the vehicle 12100. The front images acquired by the imaging units 12101 and 12105 are mainly used for detecting a preceding vehicle, a pedestrian, an obstacle, a traffic light, a traffic sign, a lane, or the like.

Note that FIG. 15 illustrates an example of imaging ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the side mirrors, respectively, and an imaging range 12114 indicates an imaging range of the imaging unit 12104 provided at the rear bumper or the back door. For example, by superimposing image data captured by the imaging units 12101 to 12104, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 obtains a distance to each three-dimensional object in the imaging ranges 12111 to 12114 and a temporal change of the distance (relative speed with respect to the vehicle 12100) on the basis of the distance information obtained from the imaging units 12101 to 12104, thereby extracting, as a preceding vehicle, a three-dimensional object traveling at a predetermined speed (for example, 0 km/h or more) in substantially the same direction as the vehicle 12100, in particular, the closest three-dimensional object on a traveling path of the vehicle 12100. Furthermore, the microcomputer 12051 can set an inter-vehicle distance to be secured in advance in front of the preceding vehicle, and can perform automatic brake control (including follow-up stop control), automatic acceleration control (including follow-up start control), and the like. As described above, it is possible to perform cooperative control for the purpose of automatic driving or the like in which the vehicle autonomously travels without depending on the operation of the driver.

For example, on the basis of the distance information obtained from the imaging units 12101 to 12104, the microcomputer 12051 can classify three-dimensional object data regarding three-dimensional objects into two-wheeled vehicles, ordinary vehicles, large vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each obstacle, and when the collision risk is a set value or more and there is a possibility of collision, the microcomputer can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not a pedestrian is present in the captured images of the imaging units 12101 to 12104. Such pedestrian recognition is performed by, for example, a procedure of extracting feature points in the captured images of the imaging units 12101 to 12104 as infrared cameras, and a procedure of performing pattern matching processing on a series of feature points indicating an outline of an object to determine whether or not the object is a pedestrian. When the microcomputer 12051 determines that a pedestrian is present in the captured images of the imaging units 12101 to 12104 and recognizes the pedestrian, the audio image output unit 12052 controls the display unit 12062 to superimpose and display a square contour line for emphasis on the recognized pedestrian. Furthermore, the audio image output unit 12052 may control the display unit 12062 to display an icon or the like indicating a pedestrian at a desired position.

An example of the vehicle control system to which the technique according to the present disclosure can be applied has been described above. The technique according to the present disclosure can be applied to, for example, the imaging unit 12031 among the above-described configurations. By applying the technique according to the present disclosure to the imaging unit 12031, it is possible to obtain a captured image with improved image quality and easier to see, and thus, it is possible to reduce driver's fatigue. Furthermore, since the height can be reduced with respect to the existing configuration, the imaging unit 12031 can be further downsized. As a result, the degree of freedom of the installation position of the imaging unit 12031 can be increased. Furthermore, since the structure for this is formed by applying pressure to the CSP solid-state imaging element 10 by the pushing tool 40, cost can be reduced.

Note that the present technique can also have configurations below.
(1) An imaging device comprising
   an imaging element including
   a solid-state imaging element on which a light receiving surface in which light receiving elements are arranged in a two-dimensional lattice pattern is formed, and
   a protection member disposed on a side of the light receiving surface with respect to the solid-state imaging element,
   wherein the imaging element includes
   a curved portion curved from the light receiving surface of the solid-state imaging element toward a surface on an opposite side of the light receiving surface.
(2) The imaging device according to the above (1), wherein
   the protection member includes
   a resin layer disposed in close contact with a side of the light receiving surface of the solid-state imaging element.
(3) The imaging device according to the above (2), wherein
   the protection member includes
   a glass substrate disposed in close contact with a surface of the resin layer on an opposite side of the light receiving surface.
(4) The imaging device according to any one of the above (1) to (3), further comprising
   a pedestal whose seat surface has a shape corresponding to the curved portion,
   wherein in the imaging element,
   a surface of the solid-state imaging element on an opposite side of the light receiving surface is disposed with respect to the seat surface of the pedestal.
(5) The imaging device according to the above (4), wherein
   the seat surface of the pedestal has
   a stepped shape.
(6) The imaging device according to the above (5), wherein
   in the pedestal,
   each of the stepped edge portions abuts on the curved portion.
(7) The imaging device according to the above (4), wherein
   the curved portion includes a first curved surface having one vertex, and
   the seat surface of the pedestal has
   a curved surface having a shape corresponding to the first curved surface.
(8) The imaging device according to the above (7), wherein
   the seat surface of the pedestal is
   in close contact with the curved portion, and the seat surface has the curved surface having the shape corresponding to the first curved surface.
(9) The imaging device according to the above (4), wherein
   the curved portion includes a second curved surface having an extreme value, and
   the seat surface of the pedestal has
   a curved surface having a shape corresponding to the second curved surface.
(10) The imaging device according to the above (9), wherein
   the seat surface of the pedestal is
   in close contact with the curved portion, and the seat surface has the curved surface having the shape corresponding to the second curved surface.
(11) The imaging device according to any one of the above (7) to (10), wherein
   the pedestal has a groove on the seat surface.
(12) The imaging device according to any one of (4) to (11), wherein
   the pedestal includes
   a material that transmits light of at least a wavelength component in an ultraviolet region.
(13) The imaging device according to any one of the above (1) to (12), wherein
   the curved portion is
   formed by applying a pressure to the imaging element with a pushing tool having a convex portion corresponding to a shape of the curved portion.
(14) The imaging device according to the above (3), further including
   a lens in close contact with a surface of the glass substrate on an opposite side of the resin layer.
(15) The imaging device according to the above (3) or (14), in which
   a refractive index of the resin layer and a refractive index of the glass substrate are substantially the same.
(16) An imaging device comprising:
   an imaging element including
   a solid-state imaging element on which a light receiving surface in which light receiving elements are arranged in a two-dimensional lattice pattern is formed, and
   a protection member disposed on a side of the light receiving surface with respect to the solid-state imaging element; and
   a lens unit including at least one lens disposed to face the light receiving surface of the imaging element,
   wherein the imaging element includes
   a curved portion curved from the light receiving surface of the solid-state imaging element toward a surface on an opposite side of the light receiving surface.
(17) The imaging device according to the above (16), in which
   the protection member includes
   a resin layer disposed in close contact with a side of the light receiving surface of the solid-state imaging element.
(18) The imaging device according to the above (17), in which
   the protection member further includes
   a glass substrate disposed in close contact with a surface of the resin layer on an opposite side of the light receiving surface.
(19) The imaging device according to any one of the above (16) to (18), further comprising
   a pedestal whose seat surface has a shape corresponding to the curved portion,
   wherein in the imaging element,
   a surface of the solid-state imaging element on an opposite side of the light receiving surface is disposed with respect to the seat surface of the pedestal.
(20) The imaging device according to the above (19), wherein
   the seat surface of the pedestal has
   a stepped shape.
(21) The imaging device according to the above (20), in which
   in the pedestal,
   each of the stepped edge portions abuts on the curved portion.
(22) The imaging device according to the above (19), wherein
   the curved portion includes a first curved surface having one vertex, and
   the seat surface of the pedestal has
   a curved surface having a shape corresponding to the first curved surface.
(23) The imaging device according to the above (22), in which
   the seat surface of the pedestal is
   in close contact with the curved portion, and the seat surface has the curved surface having the shape corresponding to the first curved surface.
(24) The imaging device according to the above (19), wherein
   the curved portion includes a second curved surface having an extreme value, and
   the seat surface of the pedestal has
   a curved surface having a shape corresponding to the second curved surface.
(25) The imaging device according to the above (24), in which
   the seat surface of the pedestal is
   in close contact with the curved portion, and the seat surface has the curved surface having the shape corresponding to the second curved surface.
(26) The imaging device according to any one of (22) to (25), wherein
   the pedestal has a groove on the seat surface.
(27) The imaging device according to any one of the (19) to (26), in which
   the pedestal includes
   a material that transmits light of at least a wavelength component in an ultraviolet region.
(28) The imaging device according to the above (18), further including
   a lens in close contact with a surface of the glass substrate on an opposite side of the resin layer.
(29) The imaging device according to any one of the above (16) to (28), in which
   the curved portion is
   formed by applying a pressure to the imaging element with a pushing tool having a convex portion corresponding to a shape of the curved portion.
(30) The imaging device according to the above (18) or (28), in which
   a refractive index of the resin layer and a refractive index of the glass substrate are substantially the same.
(31) A method of manufacturing an imaging device, the method comprising:
   a placing step of placing an imaging element including a solid-state imaging element on which a light receiving surface in which light receiving elements are arranged in a two-dimensional lattice pattern is formed, and a protection member disposed on a side of the light receiving surface with respect to the solid-state imaging element on a pedestal having a recess;
   a pressurizing step of applying a pressure to the imaging element placed on the pedestal by the placing step with a pushing tool having a convex portion corresponding to the recess; and
   a fixing step of fixing the pedestal and the imaging element to which the pressure is applied by the pressurizing step.

### REFERENCE SIGNS LIST

1a, 1b, 1c IMAGING DEVICE
10 CSP SOLID-STATE IMAGING ELEMENT
11 CIRCUIT BOARD
12a, 12b, 12c, 12d PEDESTAL
13 ADHESIVE
14 FIXING AGENT
22 SPACER
30 LENS GROUP
32 ACTUATOR
40, 41 PUSHING TOOL
120a, 120b, 120c RECESS
100 SOLID-STATE IMAGING ELEMENT
101 RESIN LAYER
102 GLASS SUBSTRATE
121 RESIN RESERVOIR
400, 410 PRESSING SURFACE

1. An imaging device comprising
an imaging element including
a solid-state imaging element on which a light receiving surface in which light receiving elements are arranged in a two-dimensional lattice pattern is formed, and
a protection member disposed on a side of the light receiving surface with respect to the solid-state imaging element,
wherein the imaging element includes
a curved portion curved from the light receiving surface of the solid-state imaging element toward a surface on an opposite side of the light receiving surface.

2. The imaging device according to claim 1, wherein
the protection member includes
a resin layer disposed in close contact with a side of the light receiving surface of the solid-state imaging element.

3. The imaging device according to claim 2, wherein
the protection member includes
a glass substrate disposed in close contact with a surface of the resin layer on an opposite side of the light receiving surface.

4. The imaging device according to claim 1, further comprising
a pedestal whose seat surface has a shape corresponding to the curved portion,
wherein in the imaging element,
a surface of the solid-state imaging element on an opposite side of the light receiving surface is disposed with respect to the seat surface of the pedestal.

5. The imaging device according to claim 4, wherein
the seat surface of the pedestal has
a stepped shape.

6. The imaging device according to claim 5, wherein
in the pedestal,
each of the stepped edge portions abuts on the curved portion.

7. The imaging device according to claim 4, wherein
the curved portion includes a first curved surface having one vertex, and
the seat surface of the pedestal has
a curved surface having a shape corresponding to the first curved surface.

8. The imaging device according to claim 7, wherein
the seat surface of the pedestal is
in close contact with the curved portion, and the seat surface has the curved surface having the shape corresponding to the first curved surface.

9. The imaging device according to claim 4, wherein
the curved portion includes a second curved surface having an extreme value, and
the seat surface of the pedestal has
a curved surface having a shape corresponding to the second curved surface.

10. The imaging device according to claim 9, wherein
the seat surface of the pedestal is
in close contact with the curved portion, and the seat surface has the curved surface having the shape corresponding to the second curved surface.

11. The imaging device according to claim 7, wherein
the pedestal has a groove on the seat surface.

12. The imaging device according to claim 4, wherein
the pedestal includes
a material that transmits light of at least a wavelength component in an ultraviolet region.

13. The imaging device according to claim 1, wherein
the curved portion is
formed by applying a pressure to the imaging element with a pushing tool having a convex portion corresponding to a shape of the curved portion.

14. An imaging device comprising:
an imaging element including
a solid-state imaging element on which a light receiving surface in which light receiving elements are arranged in a two-dimensional lattice pattern is formed, and
a protection member disposed on a side of the light receiving surface with respect to the solid-state imaging element; and
a lens unit including at least one lens disposed to face the light receiving surface of the imaging element,
wherein the imaging element includes
a curved portion curved from the light receiving surface of the solid-state imaging element toward a surface on an opposite side of the light receiving surface.

15. The imaging device according to claim 14, further comprising
a pedestal whose seat surface has a shape corresponding to the curved portion,
wherein in the imaging element,
a surface of the solid-state imaging element on an opposite side of the light receiving surface is disposed with respect to the seat surface of the pedestal.

16. The imaging device according to claim 15, wherein
the seat surface of the pedestal has
a stepped shape.

17. The imaging device according to claim 15, wherein
the curved portion includes a first curved surface having one vertex, and
the seat surface of the pedestal has
a curved surface having a shape corresponding to the first curved surface.

18. The imaging device according to claim 15, wherein
the curved portion includes a second curved surface having an extreme value, and
the seat surface of the pedestal has
a curved surface having a shape corresponding to the second curved surface.

19. The imaging device according to claim 17, wherein
the pedestal has a groove on the seat surface.

20. A method of manufacturing an imaging device, the method comprising:
a placing step of placing an imaging element including a solid-state imaging element on which a light receiving surface in which light receiving elements are arranged in a two-dimensional lattice pattern is formed, and a protection member disposed on a side of the light receiving surface with respect to the solid-state imaging element on a pedestal having a recess;
a pressurizing step of applying a pressure to the imaging element placed on the pedestal by the placing step with a pushing tool having a convex portion corresponding to the recess; and
a fixing step of fixing the pedestal and the imaging element to which the pressure is applied by the pressurizing step.
